(19) United States
(12) Patent Application Publication
(10) Pub. No.: US 2012/0194045 A1
(43) Pub. Date: Aug. 2, 2012

(54) HOUSING AND METHOD FOR MANUFACTURING SAME

(75) Inventors: SHIH-WEI YANG, Shindian (TW); KAI-RONG LIAO, Shenzhen (CN); GUO-YONG LI, Shenzhen (CN); TONG-MING LAN, Shenzhen (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/043,644

(22) Filed: Mar. 9, 2011

(30) Foreign Application Priority Data
Jan. 27, 2011 (CN) 201110029646.9

(51) Int. Cl. H05K 5/03; B65H 81/00

(52) U.S. Cl. 312/223.1; 156/194

(57) ABSTRACT

A housing includes a main body defining a mounting hole; a screen guard mounting in the mounting hole, the screen guard is glass; and a transparent layer formed on an outer surface of the main body and surrounds a peripheral surface of the screen guard. The transparent layer is made of transparent thermosetting plastic.

### BACKGROUND

1. Technical Field

The disclosure relates to housings and methods for manufacturing the housings.

2. Description of Related Art

With the development of wireless communication and information processing technology, portable electronic devices, such as mobile telephones and electronic notebooks are now widely used. The external appearance of the housing of the portable electronic device can be one of the key factors in attracting consumers.

A typical way to achieve an attractive, three-dimensional external appearance is by using insert molding. Insert molding involves placing the preformed item made of thermoplastic in a mold, then inserting a transparent thermoplastic material, such as polymer, into the mold to contact at least part of the preformed item. Then, the transparent thermoplastic material is cooled and forms a transparent layer on the preformed item. Thus, the item will have an attractive, three-dimensional appearance. However, when the transparent thermoplastic material is added, the preformed item may deform from the heat as the thermoplastic material sets.

Therefore, there is room for improvement within the art.

### BRIEF DESCRIPTION OF THE DRAWINGS

Many aspects of the present disclosure can be better understood with reference to the following drawings. These drawings are not necessarily drawn to scale, the emphasis instead being placed upon clearly illustrating the principles of the present disclosure. Moreover, in the drawings like reference numerals designate corresponding parts throughout the several views. Wherever possible, the same reference numbers are used throughout the drawings to refer to the same or like elements of an embodiment.

FIG. 1 is a schematic view of a housing according to an exemplary embodiment.

FIG. 2 is a cross-sectional view of the housing in FIG. 1.

FIG. 3 is an exploded view of housing in FIG. 1.

FIG. 4 is a schematic view of a mold for manufacturing the housing in FIG. 1.

### DETAILED DESCRIPTION

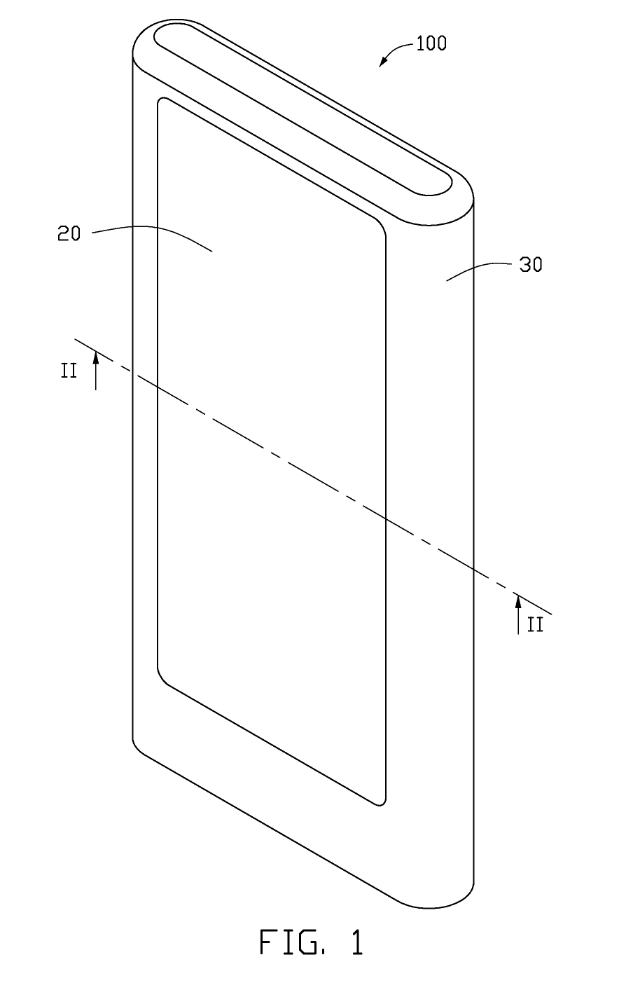

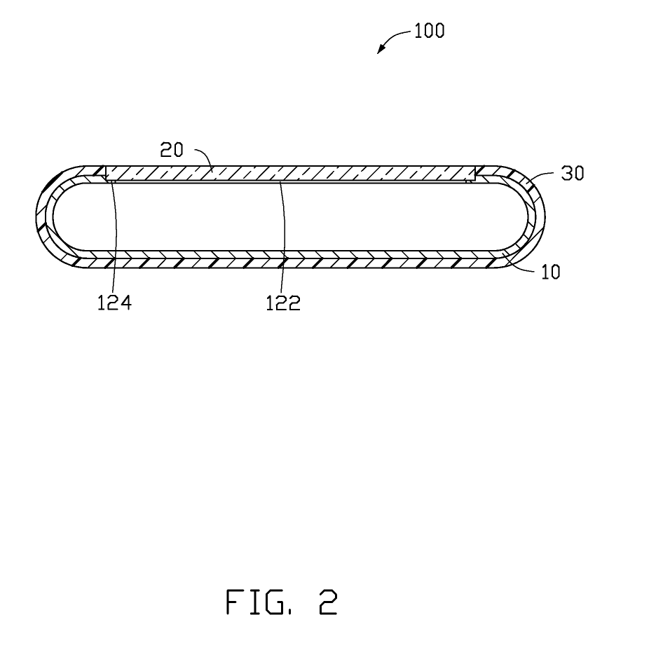

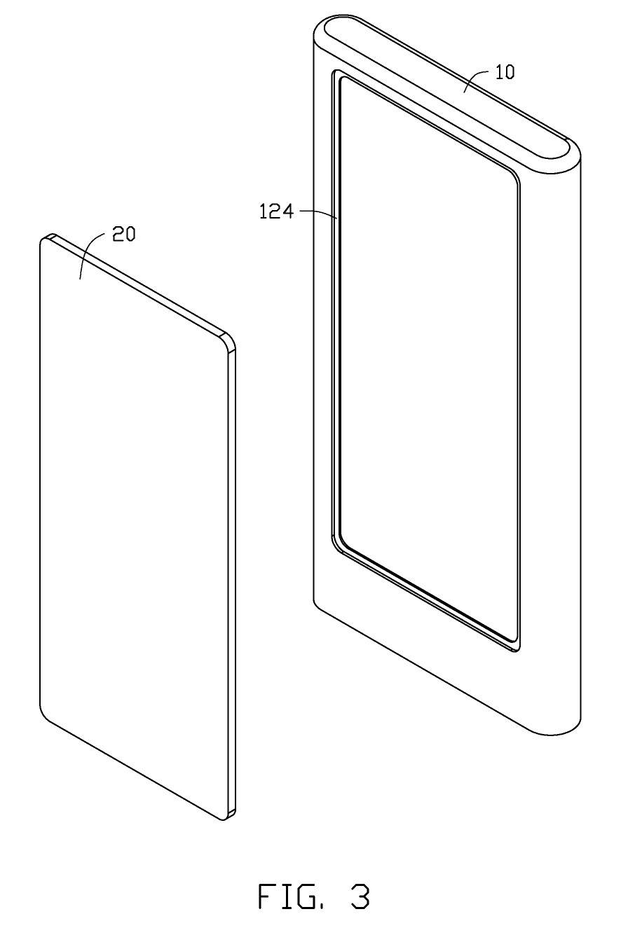

An exemplary embodiment of a housing 100 is shown in FIGS. 1 and 2. The housing 100 may be used for an electronic device, such as a mobile phone. The housing 100 is hollow, and includes a main body 10, a screen guard 20, and a transparent layer 30. Referring to FIG. 3, the main body 10 may be substantially rectangular, and defines a mounting hole 122 for mounting the screen guard 20. The main body 10 further has a ridge 124 protruding around the circumference from a portion of the wall of the mounting hole 122 surrounding the mounting hole 122. The ridge 124 supports the screen guard 20 so the screen guard 20 is firmly accommodated in the mounting hole 122. The screen guard 20 is mounted on the main body 10. The main body 10 may be made of thermoplastic. The screen guard 20 may be glass.

The transparent layer 30 is formed on an outer surface of the main body 10 and surrounds a peripheral surface of the screen guard 20. The transparent layer 30 is made of transparent thermosetting plastic, such as epoxy resin, phenolic resin, or unsaturated polyester resin. The transparent layer 30 is molded on the main body 10 by injecting transparent thermosetting plastic into a mold holding the main body 10.

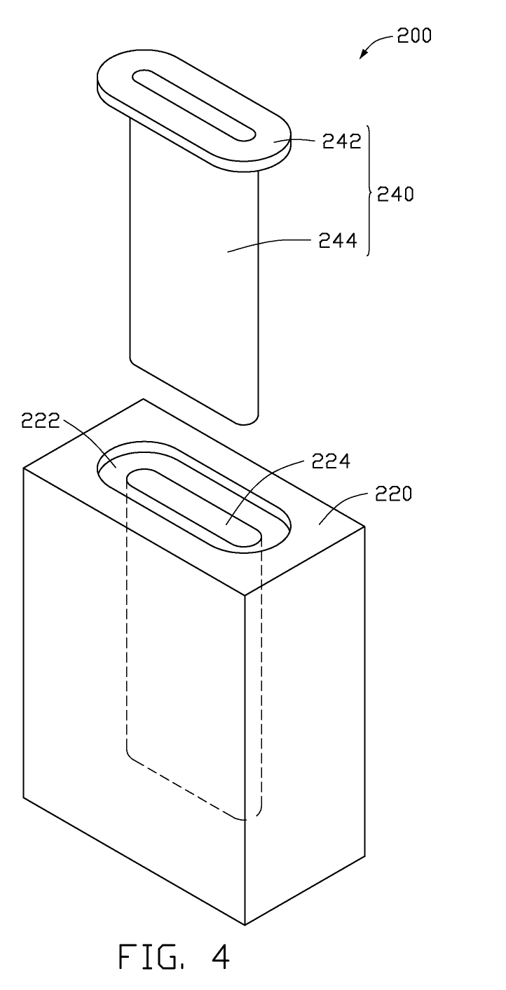

Referring to FIGS. 3-4, a method for manufacturing the housing 100 may include at least the following steps.

Referring to FIGS. 3 and 4, a main body 10 and a screen guard 20 are provided. The main body 10 includes a mounting hole 122 and the screen guard 20 is mounted in the mounting hole 122.

A mold 200 is provided. The mold 200 includes a female tool 220 and a male tool 240. The female tool 220 defines a positioning groove 222 and a mold cavity 224 in a bottom wall of the insert groove 222. The male tool 240 includes a positioning portion 242 and an insert tool 244 protruding from the positioning portion 242.

The main body 10 and the screen guard 20 are wound around the insert tool 244.

The insert tool 244 is then inserted into the mold cavity 224 until the positioning portion 242 resists the bottom wall of the insert groove 222.

Liquid transparent thermosetting plastic is provided. The transparent thermosetting plastic may be epoxy resin, phenolic resin, or unsaturated polyester resin. Liquid transparent thermosetting plastic is injected into the mold 200 until the liquid transparent thermosetting plastic contacts the surfaces of the main body 10, thus the transparent layer 30 is formed on an outer surface of the main body 10.

The liquid transparent thermosetting plastic may be set by heating the mold 20 until the transparent thermosetting plastic is set. After the transparent thermosetting plastic is set, a transparent layer 30 is formed on the main body 10.

In this exemplary embodiment, the transparent layer 30 is formed on the main body 10 by setting transparent thermosetting plastic instead of injecting thermoplastic on the main body 10, thereby preventing the main body 10 from deformation by the thermoplastic. Additionally, an attractive, three-dimensions appearance will appear on the main body 10 when viewed through the transparent layer 30.

It is to be understood, however, that even through numerous characteristics and advantages of the exemplary embodiments have been set forth in the foregoing description, together with details of the structure and function of the invention, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing for an electronic device, comprising:
a main body defining a mounting hole;
a screen guard mounted in the mounting hole, the screen guard made of glass; and
a transparent layer formed on an outer surface of the main body and surrounding a peripheral surface of the screen guard;
wherein the transparent layer is made of transparent thermosetting plastic.

2. The housing as claimed in claim 1, wherein the main body is substantially tubular.

3. The housing as claimed in claim 1, wherein the main body further has a ridge protruding from a portion of a hole wall of the mounting hole and surrounding the mounting hole, the ridge supports the screen guard when the screen guard is <?> accommodated in the mounting hole.

4. The housing as claimed in claim 1, wherein the main body is made of thermoplastic.

5. The housing as claimed in claim 1, wherein the transparent thermosetting plastic is made of epoxy resin, phenolic resin, or unsaturated polyester resin.

6. A method for manufacturing a housing of an electronic device, comprising:
providing a main body and a screen guard, the main body defining a mounting hole accommodating the screen guard therein;
providing a mold, the mold comprising a female mold and a male mold, the female mold defining a positioning groove and a mold cavity in a bottom wall of the positioning groove, the male mold comprising a positioning portion and a mounting portion protruding from the positioning portion;
winding the main body and the screen guard around the mounting portion;
inserting the mounting portion into the mold cavity until the positioning portion resists the bottom wall of the positioning groove;
injecting liquid transparent thermosetting plastic into the mold cavity until the liquid transparent thermosetting plastic contacts all the surfaces of the main body and
setting the liquid transparent thermosetting plastic to form a transparent layer on the main body.

7. The method as claimed in claim 6, wherein the transparent thermosetting plastic is made of epoxy resin, phenolic resin, or unsaturated polyester resin.

8. The method as claimed in claim 6, wherein the main body further has a ridge protruding from an inner surface of the mounting hole and surrounding the mounting hole, the ridge supports the screen guard when the screen guard is accommodated in the mounting hole.

9. A housing for an electronic device, comprising:
a main body defining a mounting hole;
a screen guard mounted in the mounting hole, the screen guard made of glass; and
a transparent layer enclosing outer surface of the main body and connecting with a peripheral surface of the screen guard, the transparent layer being formed on the main body by injecting liquid thermosetting plastic and curing thermosetting plastic.

10. The housing as claimed in claim 9, wherein the main body is substantially tubular.

11. The housing as claimed in claim 9, wherein the main body further has a ridge protruding from a portion of a hole wall of the mounting hole and surrounding the mounting hole, the ridge supports the screen guard when the screen guard is accommodated in the mounting hole.
